(19) United States
(12) Patent Application Publication
(10) Pub. No.: US 2013/0069066 A1
(43) Pub. Date: Mar. 21, 2013

(54) THIN FILM TRANSISTOR AND MANUFACTURE METHOD THEREOF

(71) Applicant: Tsunglung Chang, Shenzhen (CN)

(72) Inventor: Tsunglung Chang, Shenzhen (CN)

(73) Assignee: SHENZHEN CHINA STAR OPTOELECTRONICS TECHNOLOGY CO.,LTD., Shenzhen (CN)

(21) Appl. No.: 13/379,875

(22) PCT Filed: Sep. 27, 2011
(86) PCT No.: PCT/CN2011/080225

§ 371 Date: Dec. 21, 2011

(30) Foreign Application Priority Data
Sep. 21, 2011 (CN) 201110282067.5

(51) Int. Cl. H01L 29/786; H01L 21/336

(52) U.S. Cl. 257/57; 438/158; 257/E21.412; 257/E29.273

(57) ABSTRACT

Disclosed is a thin film transistor, comprising a first conductive layer, a first insulation layer, an amorphous silicon layer, an ohmic contact layer, a second insulation layer, a second conductive layer, a protective layer and a transparent electrode layer. The present invention also relates to a manufacture method of the thin film transistor. The thin film transistor and the manufacture method of the present invention implements merely three stages of photolithography processes to complete the manufacture of the thin film transistor, and therefore to save the manufacture cost and the process time of the thin film transistor.

### BACKGROUND OF THE INVENTION

1. Field of the Invention

The present invention generally relates to a semiconductor manufacture field, and more particularly to a thin film transistor and a manufacture method thereof capable of reducing the times of the photolithography processes.

2. Description of Prior Art

Thin film transistors have been massively applied in the manufactures of liquid crystal displays. Generally, the manufacture of the thin film transistor requires five stages of photolithography processes. Each stage of photolithography process obligates photoresist coating, exposure, development, etching and stripping processes. With the repetitious five stages of photolithography processes, the manufacture of the thin film transistor is completed. However, in the aforesaid processes, the required times of the photoresist coating, exposure and development are longer and become the bottleneck of the whole manufacture of the thin film transistor. Moreover, the cost of the stepper, the photomask and other related parts are much higher. Therefore, the repetition of the five stages of photolithography processes tremendously increases the manufacture cost and the process time of the thin film transistor.

Consequently, there is a need to provide a thin film transistor and a manufacture method thereof to solve the existing problems of prior arts.

### SUMMARY OF THE INVENTION

The present invention provide a thin film transistor and a manufacture method thereof employing three stages of photolithography processes to save the manufacture cost and the process time of the thin film transistor. The technical problems of increases of the manufacture cost and the process time in prior art due to utilizing five times of photolithography processes.

The manufacture method of the thin film transistor according to the present invention comprises steps of: S10, forming a first lamination structure on a substrate and the first lamination structure comprises a first conductive layer, a first insulation layer, an amorphous silicon layer and an ohmic contact layer from bottom to top in sequence; S20, coating a first photoresist layer to conduct a patterning process; S30, depositing a second insulation layer and conducting a stripping process to the first photoresist layer for removing the second insulation layer to expose the ohmic contact layer; S40, depositing a second conductive layer and a protective layer sequentially; S50, coating a second photoresist layer and conducting a patterning process with a half tone mask; S60, depositing a transparent electrode layer and coating a third photoresist layer to conduct a patterning process to the transparent electrode layer; In the patterning process of step S50, the amorphous silicon layer is exposed at a channel position of the thin film transistor, and then the second conductive layer is employed to form a source layer and a drain layer; In the patterning process of step S60, the transparent electrode layer contacts with a side wall of the drain layer or a side wall of the source layer; the step S10 further comprises a step of: forming a second lamination structure on the substrate and the second lamination structure comprises the first conductive layer, the first insulation layer, the amorphous silicon layer and the ohmic contact layer from bottom to top in sequence; the step S20 further comprises a step of: coating a first photoresist layer and conducting a patterning process to the first photoresist layer on the second lamination structure with a half tone mask; in the patterning process of step S20, the first insulation layer of the second lamination structure is exposed; the first insulation layer and the second insulation layer are a silicon nitride layer; the transparent electrode layer is an Indium Tin Oxide layer.

The present invention also provides a manufacture method of a thin film transistor comprises steps of: S10, forming a first lamination structure on a substrate and the first lamination structure comprises a first conductive layer, a first insulation layer, an amorphous silicon layer and an ohmic contact layer from bottom to top in sequence; S20, coating a first photoresist layer to conduct a patterning process; S30, depositing a second insulation layer and conducting a stripping process to the first photoresist layer for removing the second insulation layer to expose the ohmic contact layer; S40, depositing a second conductive layer and a protective layer sequentially; S50, coating a second photoresist layer and conducting a patterning process with a half tone mask; S60, depositing a transparent electrode layer and coating a third photoresist layer to conduct a patterning process to the transparent electrode layer.

In the manufacture method of the thin film transistor according to the present invention, in the patterning process of step S50, the amorphous silicon layer is exposed at a channel position of the thin film transistor, and then the second conductive layer is employed to form a source layer and a drain layer.

In the manufacture method of the thin film transistor according to the present invention, in the patterning process of step S60, the transparent electrode layer contacts with a side wall of the drain layer or a side wall of the source layer.

In the manufacture method of the thin film transistor according to the present invention, the step S10 further comprises a step of: forming a second lamination structure on the substrate and the second lamination structure comprises the first conductive layer, the first insulation layer, the amorphous silicon layer and the ohmic contact layer from bottom to top in sequence.

In the manufacture method of the thin film transistor according to the present invention, the step S20 further comprises a step of: coating a first photoresist layer and conducting a patterning process to the first photoresist layer on the second lamination structure with a half tone mask.

In the manufacture method of the thin film transistor according to the present invention, in the patterning process of step S20: the first insulation layer of the second lamination structure is exposed.

In the manufacture method of the thin film transistor according to the present invention, the first insulation layer and the second insulation layer are a silicon nitride layer.

In the manufacture method of the thin film transistor according to the present invention, the transparent electrode layer is an Indium Tin Oxide layer.

Another objective of the present invention is to provide a thin film transistor, comprising: a substrate, and a first conductive layer, a first insulation layer, an amorphous silicon layer and an ohmic contact layer formed on the substrate from bottom to top in sequence, the ohmic contact layer is positioned in a first area and a second area separated from each other on the amorphous silicon layer; a second insulation layer, positioned at a lateral side of the first conductive layer, the first insulation layer, the amorphous silicon layer and the ohmic contact layer; a second conductive layer, having a source layer and a drain layer, and the source layer is connected to the ohmic contact layer in the first area and the drain layer is connected to the ohmic contact layer in the second area; a protective layer, positioned on the source layer and the drain layer; and a transparent electrode layer, positioned on the protective layer and the second insulation layer and electrically connected to the source layer and the drain layer.

Another objective of the present invention is to provide a thin film transistor, comprising: a substrate, having a first lamination area and a second lamination area, the thin film transistor further comprises: a first conductive layer, a first insulation layer, an amorphous silicon layer and an ohmic contact layer formed on the first lamination area from bottom to top in sequence, the ohmic contact layer is positioned in a first area and a second area separated from each other on the amorphous silicon layer; a second insulation layer, positioned at a lateral side of the first conductive layer, the first insulation layer, the amorphous silicon layer and the ohmic contact layer; a second conductive layer, having a source layer and a drain layer, and the source layer is connected to the ohmic contact layer in the first area and the drain layer is connected to the ohmic contact layer in the second area; a protective layer, positioned on the source layer and the drain layer; and a transparent electrode layer, positioned on the protective layer and the second insulation layer and electrically connected to the source layer and the drain layer; the thin film transistor further comprises: the first conductive layer, the first insulation layer, the amorphous silicon layer formed on the second lamination area from bottom to top in sequence.

The benefit of the present invention is: the present invention implements merely three stages of photolithography processes to complete the manufacture of the thin film transistor, and therefore to save the manufacture cost and the process time of the thin film transistor comparing with the prior arts.

In the thin film transistor according to the present invention, the first insulation layer and the second insulation layer are a silicon nitride layer.

In the thin film transistor according to the present invention, the transparent electrode layer is an Indium Tin Oxide layer.

For a better understanding of the aforementioned content of the present invention, preferable embodiments are illustrated in accordance with the attached figures for further explanation:

### BRIEF DESCRIPTION OF THE DRAWINGS

FIG. 1 depicts a first structure diagram of manufacturing a first lamination structure according to the first preferable embodiment of the present invention;

FIG. 2 depicts a second structure diagram of manufacturing a first lamination structure according to the first preferable embodiment of the present invention;

FIG. 3 depicts a third structure diagram of manufacturing a first lamination structure according to the first preferable embodiment of the present invention;

FIG. 4 depicts a fourth structure diagram of manufacturing a first lamination structure according to the first preferable embodiment of the present invention;

FIG. 5 depicts a fifth structure diagram of manufacturing a first lamination structure according to the first preferable embodiment of the present invention;

FIG. 6 depicts a sixth structure diagram of manufacturing a first lamination structure according to the first preferable embodiment of the present invention;

FIG. 7 depicts a seventh structure diagram of manufacturing a first lamination structure according to the first preferable embodiment of the present invention;

FIG. 8 depicts an eighth structure diagram of manufacturing a first lamination structure according to the first preferable embodiment of the present invention;

FIG. 9 shows a manufacture flow chart of the manufacture method of the thin film transistor according to the first preferable embodiment of the present invention;

FIG. 10 depicts a first structure diagram of manufacturing a first lamination structure and a second lamination structure according to the first preferable embodiment of the present invention;

FIG. 11 depicts a second structure diagram of manufacturing a first lamination structure and a second lamination structure according to the first preferable embodiment of the present invention;

FIG. 12 depicts a third structure diagram of manufacturing a first lamination structure and a second lamination structure according to the first preferable embodiment of the present invention;

FIG. 13 depicts a fourth structure diagram of manufacturing a first lamination structure and a second lamination structure according to the first preferable embodiment of the present invention;

FIG. 14 depicts a fifth structure diagram of manufacturing a first lamination structure and a second lamination structure according to the first preferable embodiment of the present invention;

FIG. 15 depicts a sixth structure diagram of manufacturing a first lamination structure and a second lamination structure according to the first preferable embodiment of the present invention;

FIG. 16 depicts a seventh structure diagram of manufacturing a first lamination structure and a second lamination structure according to the first preferable embodiment of the present invention;

FIG. 17 depicts an eighth structure diagram of manufacturing a first lamination structure and a second lamination structure according to the first preferable embodiment of the present invention;

FIG. 18 depicts a ninth structure diagram of manufacturing a first lamination structure and a second lamination structure according to the first preferable embodiment of the present invention;

FIG. 19 shows a manufacture flow chart of the manufacture method of the thin film transistor according to the second preferable embodiment of the present invention

### DETAILED DESCRIPTION OF THE INVENTION

The following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In figures, the elements with similar structures are indicated by the same number.

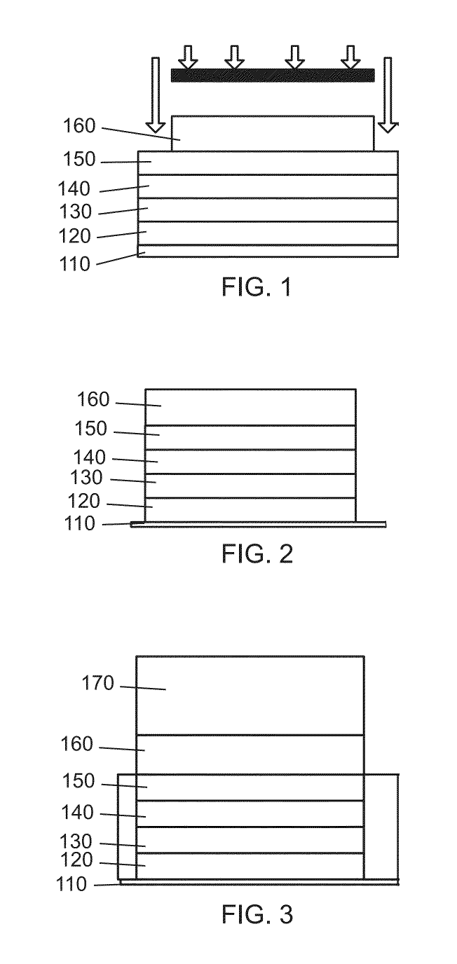

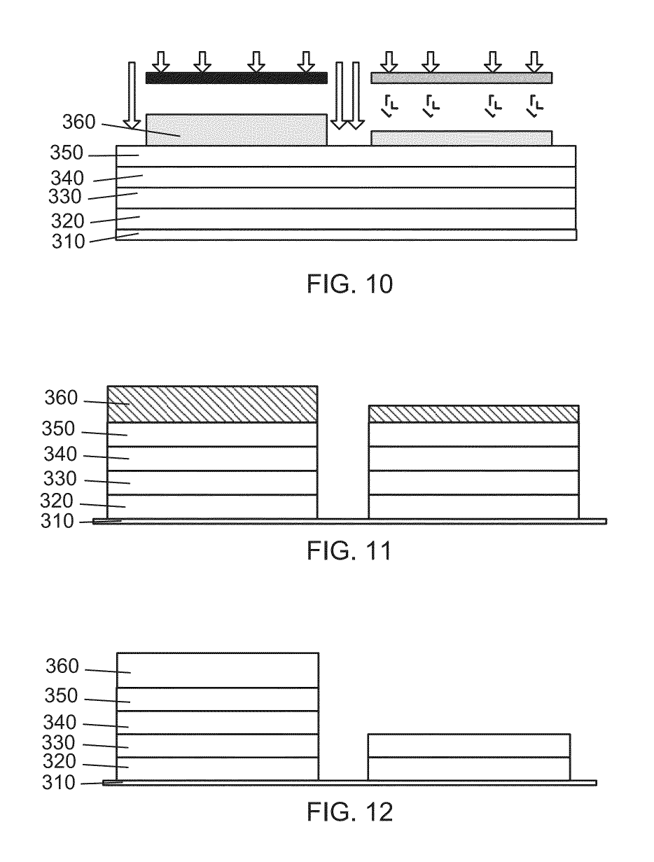

The manufacture method of the present invention employs lift off skill and half tone mask for patterning the relevant deposition layers (such as the first photoresist layer, the second photoresist layer or etc.) to achieve merely implementing three stages of photolithography processes to complete the manufacture of the thin film transistor. The first preferable embodiment of the present invention is introduced by FIG. 1 to FIG. 8. The second preferable embodiment of the present invention is introduced by FIG. 10 to FIG. 18.

The first preferable embodiment reveals manufacture processes of only a first lamination structure. As show in FIG. 1, a substrate 110 is provided, and a first conductive layer 120, a first insulation layer 130, an amorphous silicon layer 140, an ohmic contact layer 150 and a first photoresist layer 160 are deposited on the substrate 110 in sequence. Then, a mask is utilized to pattern the first photoresist layer 160 and the first lamination structure shown in FIG. 2 is formed. The first conductive layer 120, the first insulation layer 130 and the ohmic contact layer 150 can be a metal layer, a silicon oxide layer and an amorphous silicon layer implanted with phosphorous ions. The first conductive layer 120 is a gate layer of the thin film transistor.

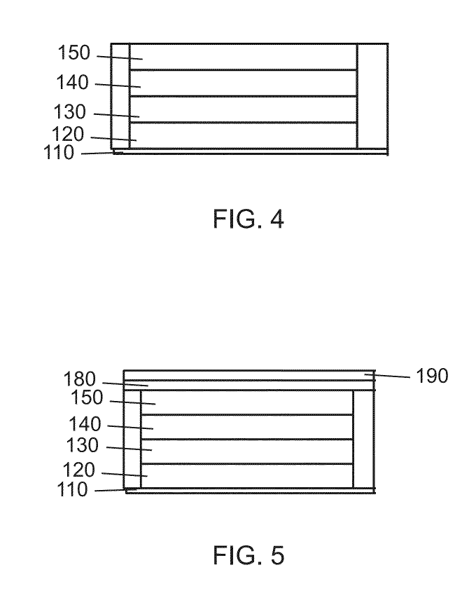

As shown in FIG. 3, a second insulation layer 170 is deposited on the first lamination structure (the second insulation layer 170 can be a silicon oxide layer). Then, a lift off skill is employed to the first lamination structure shown in FIG. 3. (lift off skill: with the gap of the photoresist layer with a certain height, the deposition thin film is ruptured. The thin film on the photoresist layer is stripped as the phtoresist layer is stripped). Because the second insulation layer 170 is formed on the first photoresist layer 160, therefore, the second insulation layer 170 on the first photoresist layer 160 is also removed as the first photoresist layer 160 is stripped as shown in FIG. 4.

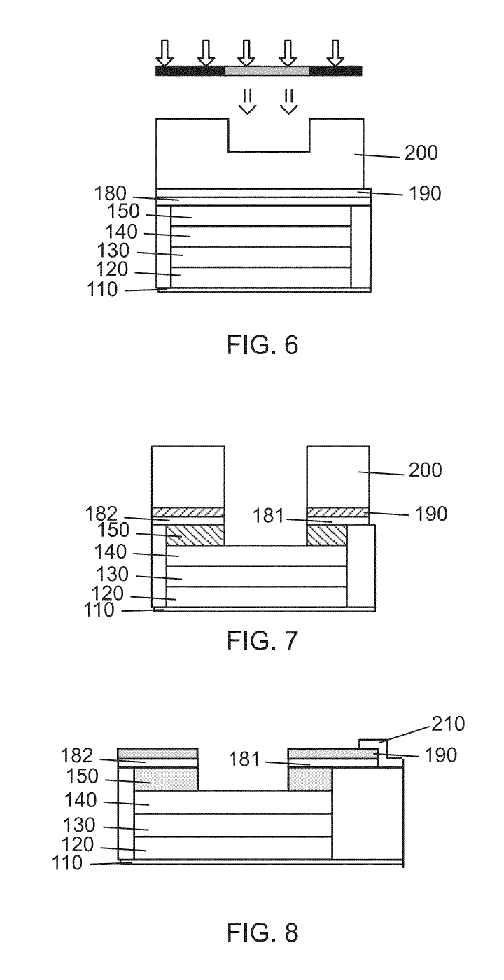

Thereafter, as shown in FIG. 5, a second conductive layer 180 and a protective layer 190 are deposited (generally, an insulation layer, such as a silicon nitride layer). As shown in FIG. 6, a half tone mask is employed for patterning a second photoresist layer 200 (two sides of the half tone mask is opaque and the middle of the half tone mask is semiopaque). By conducting an etching process to the surface of the first lamination structure, the amorphous silicon layer 140 is exposed at a channel position of the thin film transistor, and then the ohmic contact layer 150 is positioned in a first area and a second area, which are separated from each other on the amorphous silicon layer (shown in FIG. 7). Then, a conductive source layer 181 and a conductive drain layer 182 are formed. The source layer 181 is connected to the ohmic contact layer 150 in the first area and the drain layer 182 is connected to the ohmic contact layer 150 in the second area. The first conductive layer 120 and the second conductive layer 180 can be metal layers, such as nobelium, molybdenum, aluminum, copper, titanium, tantalum, wolfram or etc.

Last, as shown in FIG. 8, a transparent electrode layer 210 is deposited and a third photoresist layer (not shown) is coated for conducting a patterning process to the transparent electrode layer 210 after the second photoresist layer 200 is stripped. The transparent electrode layer 210 on the protective layer 190 and the second insulation layer 170 which is connected to the source layer 181 (i.e. a portion of the second conductive layer 180) as shown in FIG. 8 is formed. The transparent electrode layer 210 can be formed by ITO, indium-tin-oxide. Certainly, the transparent electrode layer 210 also can be connected to the drain layer 182 on demand.

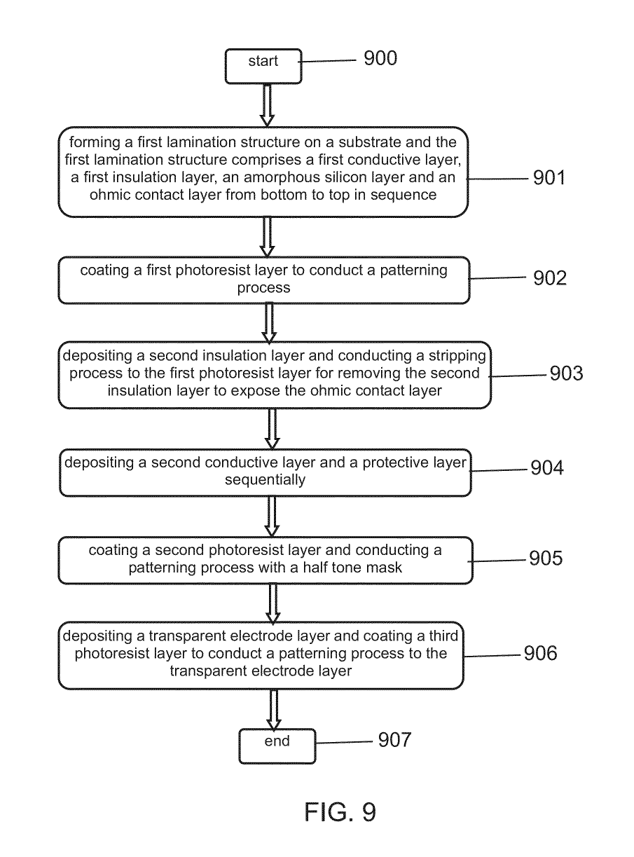

FIG. 9 shows a manufacture flow chart of the manufacture method of the thin film transistor according to the first preferable embodiment of the present invention. The manufacture method of the thin film transistor starts at step 900 and then is followed:

Step 901, forming a first lamination structure on a substrate and the first lamination structure comprises a first conductive layer, a first insulation layer, an amorphous silicon layer and an ohmic contact layer from bottom to top in sequence;

Step 902, coating a first photoresist layer to conduct a patterning process;

Step 903, depositing a second insulation layer and conducting a stripping process to the first photoresist layer for removing the second insulation layer to expose the ohmic contact layer;

Step 904, depositing a second conductive layer and a protective layer sequentially;

Step 905, coating a second photoresist layer and conducting a patterning process with a half tone mask;

Step 906, depositing a transparent electrode layer and coating a third photoresist layer to conduct a patterning process to the transparent electrode layer; Ultimately, the manufacture method of the thin film transistor ends at step 907.

According to the first preferable embodiment shown from FIG. 1 to FIG. 8 and the flowchart of the manufacture method of the thin film transistor shown in FIG. 9, merely three stages of photolithography processes shown in FIG. 1, FIG. 6 and FIG. 8 are necessary to be conducted. Comparing to the manufacture methods of the prior arts, two stages of photolithography processes can be omitted to save the manufacture cost and the process time of the thin film transistor.

FIG. 10 to FIG. 18 show structure diagrams of manufacturing a first lamination structure and a second lamination structure according to the first preferable embodiment of the present invention (The first lamination structure and the second lamination structure comprise different layer components and the second lamination structure is employed as being a common electrode). First, as shown in FIG. 10, a substrate 310 having a first lamination area and a second lamination area is provided. A first lamination structure is formed on the first lamination area of the substrate 310 and a second lamination structure is formed on the second lamination area of the substrate 310. The first lamination structure comprises a first conductive layer 320, a first insulation layer 330, an amorphous silicon layer 340, an ohmic contact layer 350 and a first photoresist layer 360 from bottom to top in sequence. The second lamination structure comprises the first conductive layer 320, the first insulation layer 330, the amorphous silicon layer 340, the ohmic contact layer 350 and the first photoresist layer 360 from bottom to top in sequence. Then, a half tone mask is employed for conducting a patterning process to the first photoresist layer 360 (a portion of the half tone mask for the first lamination structure is opaque, a portion of the half tone mask for the second lamination structure is semiopaque). By conducting an etching process, the first lamination structure and the second lamination structure shown in FIG. 11 are formed. The first photoresist layer 360 on the first lamination structure has a first thickness. The first photoresist layer 360 on the second lamination structure has a second thickness. The second thickness is smaller than the first thickness. The first conductive layer 320, the first insulation layer 330 and the ohmic contact layer 350 can be a metal layer, a silicon oxide layer and an amorphous silicon layer implanted with phosphorous ions.

As shown in FIG. 12, a photoresist ashing process is conducted to the first lamination structure and the second lamination structure. Because the first photoresist layer 360 on the second lamination structure is thinner, the ohmic contact layer 350 and the amorphous silicon layer 340 under the photoresist layer 360 are not protected and removed after the photoresist ashing process; the first photoresist layer 360 on the first lamination structure is thicker, the ohmic contact layer 350 and the amorphous silicon layer 340 hereunder are protected before the ohmic contact layer 350 and the amorphous silicon layer 340 of the second lamination structure are entirely removed and the first insulation layer 330 of the second lamination structure is exposed. At this stage, the first lamination structure still comprises the first conductive layer 320, the first insulation layer 330, the amorphous silicon layer 340, the ohmic contact layer 350 and the first photoresist layer 360. The second lamination structure comprises the first conductive layer 320 and the first insulation layer 330. The etching rate in this step of the present invention can be determined according to real demand. For example, the first insulation layer 330 in the second lamination structure also can be removed optionally.

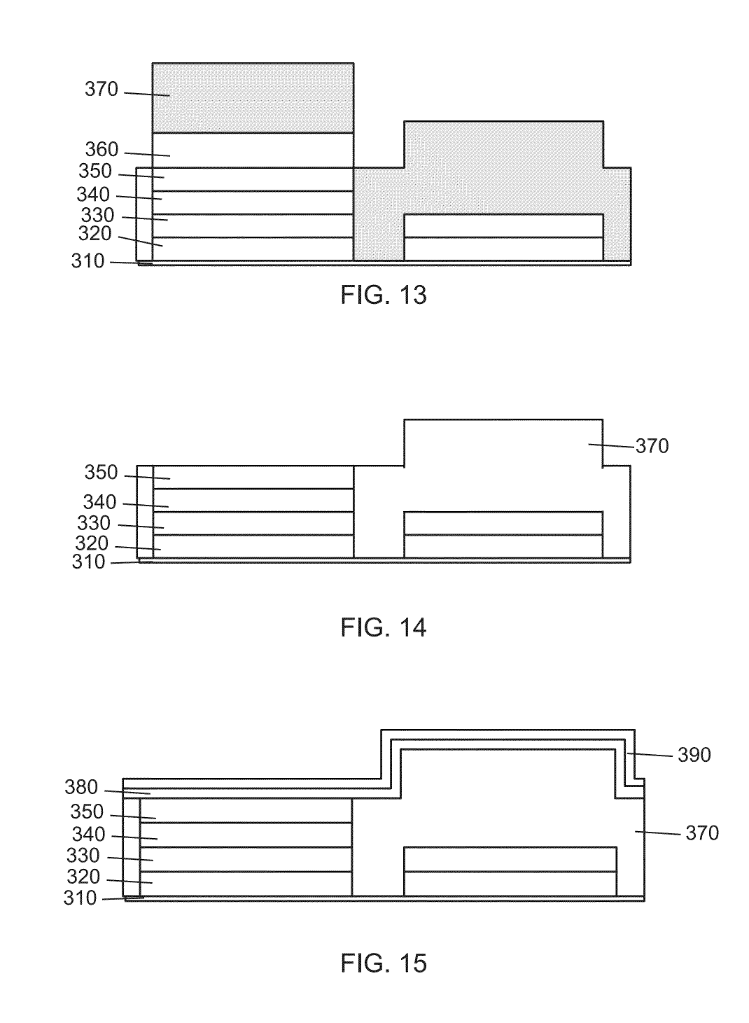

As shown in FIG. 13, a second insulation layer 370 is deposited on the first lamination structure and the second lamination structure. Then, a lift off skill is employed to the first lamination structure shown in FIG. 13. Because the second insulation layer 370 is formed on the first photoresist layer 360, therefore, the second insulation layer 370 on the first photoresist layer 360 is also removed as the first photoresist layer 360 is stripped as shown in FIG. 14.

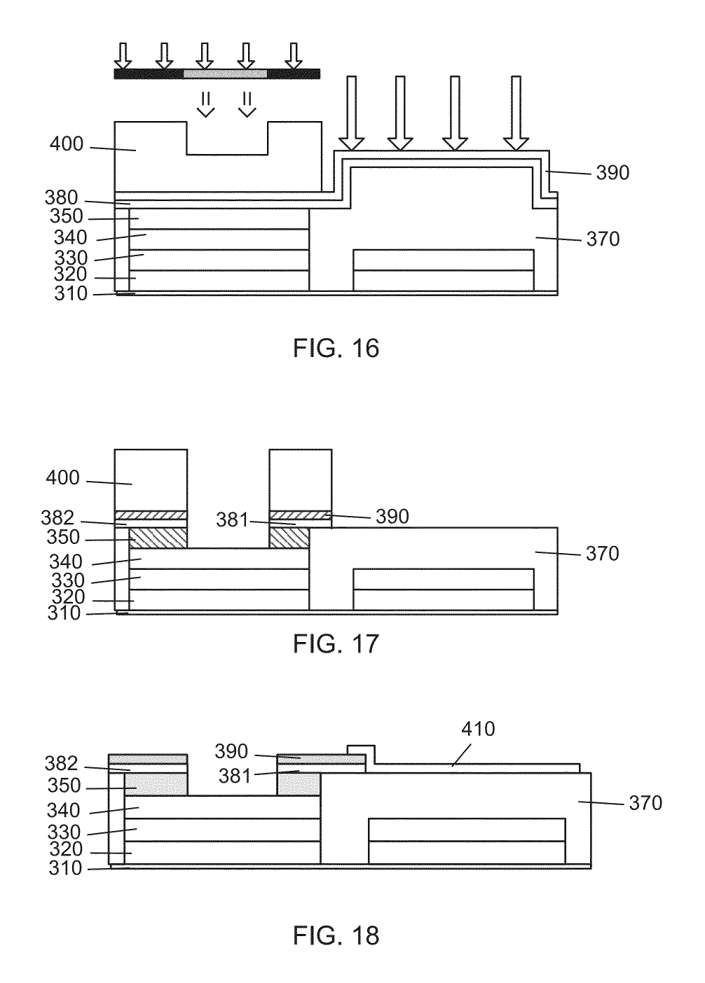

Thereafter, as shown in FIG. 15, a second conductive layer 380 and a protective layer 390 are deposited (generally, an insulation layer, such as a silicon nitride layer). As shown in FIG. 16, a half tone mask is employed for patterning a second photoresist layer 400 (two sides of the half tone mask is opaque and the middle of the half tone mask is semiopaque). By conducting an etching process to the surface of the first lamination structure, the amorphous silicon layer 340 is exposed at a channel position of the thin film transistor, and then the ohmic contact layer 350 is positioned in a first area and a second area, which are separated from each other on the amorphous silicon layer (shown in FIG. 17). Meanwhile, second insulation layer 370 of the second lamination structure is exposed. At this stage, a conductive source layer 381 and a conductive drain layer 382 are formed. The source layer 381 is connected to the ohmic contact layer 350 in the first area and the drain layer 382 is connected to the ohmic contact layer 350 in the second area. The first conductive layer 320 and the second conductive layer 380 can be metal layers, such as nobelium, molybdenum, aluminum, copper, titanium, tantalum, wolfram or etc.

Last, as shown in FIG. 18, a transparent electrode layer 410 is deposited and a third photoresist layer (not shown) is coated for conducting a patterning process to the transparent electrode layer 410 after the second photoresist layer 400 is stripped. The transparent electrode layer 410 on the protective layer 390 and the second insulation layer 370 which is connected to the source layer 381 (i.e. a portion of the second conductive layer 380) as shown in FIG. FIG. 18 is formed. The transparent electrode layer 410 can extend to the top of the second lamination structure. The transparent electrode layer 410 can be formed by ITO, indium-tin-oxide and respectively connected to the source layer 381 and the gate electrode layer. The transparent electrode layer 410 connected to the source layer 381 can be employed as being a pixel electrode (The connection of the gate electrode layer and the transparent electrode layer 410 can finished in the post circuit manufacture or completed as manufacturing the thin film transistor at the same time). Certainly, the transparent electrode layer 410 also can be connected to the drain layer 382 on demand.

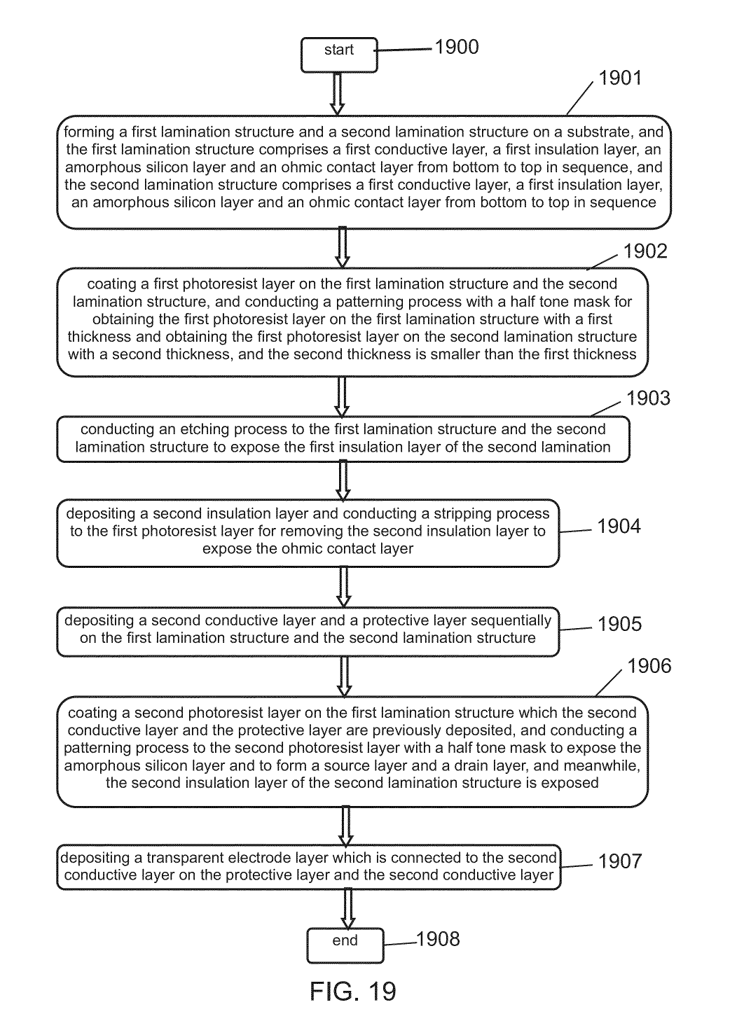

FIG. 19 shows a manufacture flow chart of the manufacture method of the thin film transistor according to the second preferable embodiment of the present invention. The manufacture method of the thin film transistor starts at step 1900 and then is followed:

Step 1901, forming a first lamination structure and a second lamination structure on a substrate, and the first lamination structure comprises a first conductive layer, a first insulation layer, an amorphous silicon layer and an ohmic contact layer from bottom to top in sequence, and the second lamination structure comprises a first conductive layer, a first insulation layer, an amorphous silicon layer and an ohmic contact layer from bottom to top in sequence;

Step 1902, coating a first photoresist layer on the first lamination structure and the second lamination structure, and conducting a patterning process with a half tone mask for obtaining the first photoresist layer on the first lamination structure with a first thickness and obtaining the first photoresist layer on the second lamination structure with a second thickness, and the second thickness is smaller than the first thickness;

Step 1903, conducting an etching process to the first lamination structure and the second lamination structure to expose the first insulation layer of the second lamination structure;

Step 1904, depositing a second insulation layer and conducting a stripping process to the first photoresist layer for removing the second insulation layer to expose the ohmic contact layer;

Step 1905, depositing a second conductive layer and a protective layer sequentially on the first lamination structure and the second lamination structure;

Step 1906, coating a second photoresist layer on the first lamination structure which the second conductive layer and the protective layer are previously deposited, and conducting a patterning process to the second photoresist layer with a half tone mask to expose the amorphous silicon layer and to form a source layer and a drain layer, and meanwhile, the second insulation layer of the second lamination structure is exposed;

Step 1907, depositing a transparent electrode layer which is connected to the second conductive layer on the protective layer and the second conductive layer; Ultimately, the manufacture method of the thin film transistor ends at step 1907.

According to the first preferable embodiment shown from FIG. 10 to FIG. 18 and the flowchart of the manufacture method of the thin film transistor shown in FIG. 19, merely three stages of photolithography processes shown in FIG. 10, FIG. 16 and FIG. 18 are necessary to be conducted. Comparing to the manufacture methods of the prior arts, two stages of photolithography processes can be omitted to save the manufacture cost and the process time of the thin film transistor.

The present invention also relates with a thin film transistor. The thin film transistor of the present invention can comprise the first lamination structure only. Alternatively, the thin film transistor of the present invention can comprise the first lamination structure and the second lamination structure simultaneously.

As the thin film transistor of the present invention merely comprises the first lamination structure, the thin film transistor comprises a substrate, and a first conductive layer, a first insulation layer, an amorphous silicon layer and an ohmic contact layer formed on the substrate from bottom to top in sequence. The ohmic contact layer is positioned in a first area and a second area separated from each other on the amorphous silicon layer; a second insulation layer, positioned at a lateral side of the first conductive layer, the first insulation layer, the amorphous silicon layer and the ohmic contact layer; a second conductive layer, having a source layer and a drain layer, and the source layer is connected to the ohmic contact layer in the first area and the drain layer is connected to the ohmic contact layer in the second area; a protective layer, positioned on the source layer and the drain layer; and a transparent electrode layer, positioned on the protective layer and the second insulation layer and electrically connected to the source layer and the drain layer.

The manufacture of the aforesaid thin film transistor merely requires three stages of photolithography processes (Please refer to the specific embodiments of the manufacture method of the thin film transistor in detail). Comparing with the traditional methods of the prior arts, two stages of photolithography processes can be omitted to save the manufacture cost and the process time of the thin film transistor.

As the thin film transistor of the present invention comprises the first lamination structure and the second lamination structure simultaneously, the thin film transistor comprises a substrate having a first lamination area and a second lamination area. The thin film transistor further comprises: a first conductive layer, a first insulation layer, an amorphous silicon layer and an ohmic contact layer formed on the first lamination area from bottom to top in sequence. The ohmic contact layer, positioned in a first area and a second area separated from each other on the amorphous silicon layer; a second insulation layer, positioned at a lateral side of the first conductive layer, the first insulation layer, the amorphous silicon layer and the ohmic contact layer; a second conductive layer, having a source layer and a drain layer, and the source layer is connected to the ohmic contact layer in the first area and the drain layer is connected to the ohmic contact layer in the second area; a protective layer, positioned on the source layer and the drain layer; and a transparent electrode layer, positioned on the protective layer and the second insulation layer and electrically connected to the source layer and the drain layer; the thin film transistor further comprises: the first conductive layer, the first insulation layer, the second insulation layer and the transparent electrode layer formed on the second lamination area from bottom to top in sequence. The manufacture of the aforesaid thin film transistor merely requires three stages of photolithography processes (Please refer to the specific embodiments of the manufacture method of the thin film transistor in detail). Comparing with the traditional methods of the prior arts, two stages of photolithography processes can be omitted to save the manufacture cost and the process time of the thin film transistor.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A manufacture method of a thin film transistor, characterized in comprising steps of:
S10, forming a first lamination structure on a substrate and the first lamination structure comprises a first conductive layer, a first insulation layer, an amorphous silicon layer and an ohmic contact layer from bottom to top in sequence;
S20, coating a first photoresist layer to conduct a patterning process;
S30, depositing a second insulation layer and conducting a stripping process to the first photoresist layer for removing the second insulation layer to expose the ohmic contact layer;
S40, depositing a second conductive layer and a protective layer sequentially;
S50, coating a second photoresist layer and conducting a patterning process with a half tone mask;
S60, depositing a transparent electrode layer and coating a third photoresist layer to conduct a patterning process to the transparent electrode layer;
In the patterning process of step S50, the amorphous silicon layer is exposed at a channel position of the thin film transistor, and then the second conductive layer is employed to form a source layer and a drain layer;
In the patterning process of step S60, the transparent electrode layer contacts with a side wall of the drain layer or a side wall of the source layer;
the step S10 further comprises a step of:
forming a second lamination structure on the substrate and the second lamination structure comprises the first conductive layer, the first insulation layer, the amorphous silicon layer and the ohmic contact layer from bottom to top in sequence;
the step S20 further comprises a step of:
coating a first photoresist layer and conducting a patterning process to the first photoresist layer on the second lamination structure with a half tone mask;
in the patterning process of step S20, the first insulation layer of the second lamination structure is exposed;
the first insulation layer and the second insulation layer are a silicon nitride layer;
the transparent electrode layer is an Indium Tin Oxide layer.

2. A manufacture method of a thin film transistor, characterized in comprising steps of:
S10, forming a first lamination structure on a substrate and the first lamination structure comprises a first conductive layer, a first insulation layer, an amorphous silicon layer and an ohmic contact layer from bottom to top in sequence;
S20, coating a first photoresist layer to conduct a patterning process;
S30, depositing a second insulation layer and conducting a stripping process to the first photoresist layer for removing the second insulation layer to expose the ohmic contact layer;
S40, depositing a second conductive layer and a protective layer sequentially;
S50, coating a second photoresist layer and conducting a patterning process with a half tone mask;
S60, depositing a transparent electrode layer and coating a third photoresist layer to conduct a patterning process to the transparent electrode layer.

3. The manufacture method of the thin film transistor according to claim 2, characterized in that in the patterning process of step S50, the amorphous silicon layer is exposed at a channel position of the thin film transistor, and then the second conductive layer is employed to form a source layer and a drain layer.

4. The manufacture method of the thin film transistor according to claim 3, characterized in that in the patterning process of step S60, the transparent electrode layer contacts with a side wall of the drain layer or a side wall of the source layer.

5. The manufacture method of the thin film transistor according to claim 2, characterized in that the step S10 further comprises a step of:
forming a second lamination structure on the substrate and the second lamination structure comprises the first conductive layer, the first insulation layer, the amorphous silicon layer and the ohmic contact layer from bottom to top in sequence.

6. The manufacture method of the thin film transistor according to claim 5, characterized in that the step S20 further comprises a step of:
coating a first photoresist layer and conducting a patterning process to the first photoresist layer on the second lamination structure with a half tone mask.

7. The manufacture method of the thin film transistor according to claim 6, characterized in that in the patterning process of step S20: the first insulation layer of the second lamination structure is exposed.

8. The manufacture method of the thin film transistor according to claim 2, characterized in that the first insulation layer and the second insulation layer are a silicon nitride layer.

9. The manufacture method of the thin film transistor according to claim 2, characterized in that the transparent electrode layer is an Indium Tin Oxide layer.

10. A thin film transistor, characterized in comprising:
a substrate, and
a first conductive layer, a first insulation layer and an amorphous silicon layer formed on the substrate from bottom to top in sequence,
an ohmic contact layer, positioned in a first area and a second area separated from each other on the amorphous silicon layer;
a second insulation layer, positioned at a lateral side of the first conductive layer, the first insulation layer, the amorphous silicon layer and the ohmic contact layer;
a second conductive layer, having a source layer and a drain layer, and the source layer is connected to the ohmic contact layer in the first area and the drain layer is connected to the ohmic contact layer in the second area;
a protective layer, positioned on the source layer and the drain layer; and
a transparent electrode layer, positioned on the protective layer and the second insulation layer and electrically connected to the source layer and the drain layer.

11. The thin film transistor according to claim 10, characterized in that the first insulation layer and the second insulation layer are a silicon nitride layer.

12. The thin film transistor according to claim 10, characterized in that the transparent electrode layer is an Indium Tin Oxide layer.

13. A thin film transistor, characterized in comprising:
a substrate, having a first lamination area and a second lamination area, the thin film transistor further comprises:
a first conductive layer, a first insulation layer and an amorphous silicon layer formed on the first lamination area from bottom to top in sequence, an ohmic contact layer, positioned in a first area and a second area separated from each other on the amorphous silicon layer;
a second insulation layer, positioned at a lateral side of the first conductive layer, the first insulation layer, the amorphous silicon layer and the ohmic contact layer;
a second conductive layer, having a source layer and a drain layer, and the source layer is connected to the ohmic contact layer in the first area and the drain layer is connected to the ohmic contact layer in the second area;
a protective layer, positioned on the source layer and the drain layer; and
a transparent electrode layer, positioned on the protective layer and the second insulation layer and electrically connected to the source layer and the drain layer;
the thin film transistor further comprises:
the first conductive layer, the first insulation layer, the second insulation layer and the transparent electrode layer formed on the second lamination area from bottom to top in sequence.

14. The thin film transistor according to claim 13, characterized in that the first insulation layer and the second insulation layer are a silicon nitride layer.

15. The thin film transistor according to claim 13, characterized in that the transparent electrode layer is an Indium Tin Oxide layer.
